(19) United States
(12) Patent Application Publication
(10) Pub. No.: US 2017/0252756 A1
(43) Pub. Date: Sep. 7, 2017

(54) SHOWER HEAD AND FILM FORMING APPARATUS

(71) Applicant: TOKYO ELECTRON LIMITED, Tokyo (JP)

(72) Inventor: Yoji IIZUKA, Tokyo (JP)

(21) Appl. No.: 15/510,992

(22) PCT Filed: Aug. 31, 2015
(86) PCT No.: PCT/JP2015/074703

§ 371 Date: Mar. 13, 2017

(30) Foreign Application Priority Data
Sep. 17, 2014 (JP) 2014-188689

(51) Int. Cl. B05B 1/18; C23C 16/455

(52) U.S. Cl. CPC B05B 1/185; C23C 16/45565; C23C 16/45544

(57) ABSTRACT

A shower head for a film forming apparatus is provided. The shower head includes: a gas injection plate provided with a plurality of gas injection holes extending in the thickness direction thereof; and a gas supply unit that provides a plurality of flow paths that guide gas to the plurality of gas injection holes from a common flow path, each of the plurality of flow paths having one end connected to the common flow path and the other end. Among the flow paths, any two paths that satisfy the condition of a first linear distance between the positions of the ends of one flow path being shorter than a second linear distance between the positions of the ends of the other flow path have a relationship wherein the difference between the length of the one flow path and the first linear distance is larger than the difference between the length of the other flow path and the second linear distance.

### CROSS-REFERENCE TO RELATED APPLICATIONS

This application is a National Stage Application of, and claims priority to, PCT Application No. PCT/JP2015/074703, filed on Aug. 31, 2015, entitled “SHOWER HEAD AND FILM FORMING APPARATUS,” which claims priority to Japanese Patent Application No. 2014-188689, filed on Sep. 17, 2014. The foregoing patent applications are herein incorporated by reference by entirety for all purposes.

### FIELD OF THE INVENTION

The present invention relates to a shower head and a film forming apparatus.

### BACKGROUND OF THE INVENTION

In manufacturing electronic devices such as semiconductor device, a liquid crystal display and the like, a thin film may be formed on a target object by using a film forming method such as a CVD (Chemical Vapor Deposition) method, an AID (Atomic Layer Deposition) method or the like. In such a film forming method, it is required to form a thin film uniformly on the surface of the target object. There is known a film forming apparatus including a shower head for injecting a film forming gas to the target object in a shower shape in order to uniformly form a thin film on the surface of the target object.

For example, film forming apparatuses, each including a shower head, are disclosed in Patent Documents 1 to 4. Each of the film forming apparatuses of Patent Documents 1 to 4 includes a processing chamber, a mounting table, and the shower head. The processing chamber defines therein a processing space for processing a target object. The mounting table is provided in the processing chamber and mounts thereon the target object. The shower head is provided above the mounting table and supplies a film forming gas toward the target object mounted on the mounting table.

Each of the shower heads disclosed in Patent Documents 1 to 4 has therein a gas diffusion space. In the gas diffusion space, the film forming gas supplied from a gas source is diffused. The gas diffusion space communicates with a plurality of gas injection holes opened to the processing space. The shower head allows the gas supplied from the gas source to be diffused in the gas diffusion space and also allows the diffused processing gas to be injected toward the target object through the gas in holes. However, in the shower head having therein the gas diffusion space, a gas may remain in the gas diffusion space when gases are switched and, thus, the processing gas in the shower head may not be efficiently discharged (purged). As a result, different gases are mixed and particles may be generated on the target object.

Patent Document 5 discloses a shower head capable of efficiently discharging a gas therefrom. This shower head has a plurality of tubes having one ends connected to a plurality of gas injection holes. The other ends of the tubes are connected to a gas supply passageway. The shower head disclosed in Patent Document 5 does not have therein a space where a gas remains, so that a gas in the shower head can be replaced within a short period of time.

Patent Document 1: International Publication No. 2013/015281

Patent Document 2: Japanese Patent Application Publication No. 2009-524244

Patent Document 3: Japanese Patent Application Publication No. 2007-27490

Patent Document 4: Japanese Patent Application Publication No. 2008-297597

Patent Document 5: Japanese Patent Application Publication No. 2004-277772

However, in the shower head of Patent Document 5, a flow rate of a gas injected through the gas injection holes varies depending on formation positions of the gas injection holes. When the flow rate of the injected gas varies depending on the formation positions of the gas injection holes, a film thickness of a formed film varies depending on positions in the surface of the target object. This leads to deterioration of in-plane uniformity of film formation.

### SUMMARY OF THE INVENTION

Therefore, in this technical field, it is required to reduce a different in the flow rate of the gas injected through the gas injection holes.

In accordance with an aspect, there is provided a shower head for a film forming apparatus. The shower head includes: a gas injection plate provided with a plurality of gas injection holes extending in a thickness direction thereof; and a gas supply unit configured to provide a plurality of flow paths that guide gas to at least a part of the plurality of gas injection holes from a common flow path, each of the plurality of flow paths having one end connected to the common flow path and the other end. Among plurality of flow paths, any two flow paths that satisfy a condition that a first linear distance between positions of one end and the other end of one flow path is shorter than a second linear distance between positions of one end and the other end of the other flow path have a relationship in which a difference between a length of the one flow path and the first linear distance is larger than a difference between a length of the other flow path and the second linear distance.

In the shower head in accordance with the aspect, the other end of the one of the two flow paths is separated from the connection position thereof to the common flow path by the first linear distance. The other end of the other of the two flow paths is separated from the connection position thereof to the common flow path by the second linear distance. In the shower head having such configurations, if the one flow path and the other flow path are each linearly provided between the one end and the other end thereof, there is a difference in the length between the two flow paths, which causes a difference in conductance therebetween. In contrast, in the shower head in accordance with the aspect, the two flow paths have a relationship in which the difference between the length of the one flow path and the first linear distance is larger than the difference between the length of the other flow path and the second linear distance. The difference in length between the two flow paths can be reduced. Accordingly, the difference in conductance between the flow paths, which results in reduction of the difference between the flow rates of the gas injected through the gas injection holes.

The gas supply unit may further provide branch flow paths that connect the other end of at least one of the plurality of flow paths to at least a few gas injection holes among the plurality of gas injection holes. With such configurations, the number of the flow paths can be reduced and, thus, the shower head can be scaled down.

The gas supply unit may have a plurality of tubes that provides the plurality of flow paths and the plurality of tubes are flexible. Further, the gas supply unit may have a block-shaped member provided with a plurality of channels and the plurality of channels form the plurality of flow paths. In the case where with the channels formed in the block-shaped member serve as the flow paths, the number of components of the shower head can be reduced. The block shaped body may is formed by using a 3D printer, which makes it possible to form a block-shaped member having a complex shape.

The gas supply unit may further provide a plurality of other flow paths that guide gas to at least a part of the plurality of gas injection holes from another common flow path, each of the plurality of other flow paths including one end connected to the another common flow path and the other end, and among the plurality of other flow paths, any two paths that satisfy a condition that a third linear distance between positions of one end and the other end of one flow path is shorter than a fourth linear distance between positions of one end and the other end of the other flow path have a relationship in which a difference between a length of the one flow path and the third linear distance is larger than a difference between a length of the other flow path and the fourth linear distance. With such configurations, it is possible to securely prevent the gas supplied from the common flow path and the gas supplied from the another flow path from being mixed.

The plurality of gas injection holes may be arranged in a first direction orthogonal to a thickness direction of the gas injection plate and in a second direction orthogonal to the thickness direction and the first direction, and the other ends of the plurality of flow paths and the other ends of the plurality of other flow paths may be alternately connected to the plurality of gas injection holes in the first direction and the second direction. With such configurations, the other ends of the plurality of flow paths and the other ends of the plurality of other flow paths are alternately connected to the plurality of gas injection holes in the first direction and the second direction, so that it is possible to uniformly distribute the gas from the common flow path and the gas from the another flow path toward the lower side of the gas injection plate. Further, the gas injection plate may have a disc shape, the plurality of gas injection holes may be arranged along a circumferential direction and a radial direction of the gas injection plate when viewed from the thickness direction, and the other ends of the plurality of flow paths and the other ends of the plurality of other flow paths may be alternately connected to the plurality of gas injection holes in the circumferential direction and the radial direction.

In accordance with another aspect, there is provided a film forming apparatus comprising the shower head described above.

### Effect of the Invention

In accordance with the aspects and the embodiments of the present invention, the difference between the flow rates of the gases injected through the gas injection holes can be reduced.

### BRIEF DESCRIPTION OF THE DRAWINGS

FIG. 1 is a schematic cross sectional view showing a configuration of a film forming apparatus according to an embodiment.

FIG. 2 is a schematic cross sectional vies showing a shower head according to an embodiment.

FIG. 3 is a perspective view of a gas injection plate.

FIG. 4 is a schematic cross sectional view showing any two tubes among a plurality of tubes shown in FIG. 2.

FIG. 5A is a time chart showing flow rates of gases supplied to a reservoir, and FIG. 5B shows timings of injection of gases through a first and a second gas injection hole.

FIG. 6 is a schematic cross sectional view of a shower head according to another embodiment.

FIG. 7 is a schematic cross sectional view of a shower head according to still another embodiment.

FIG. 8 is a schematic cross sectional view of a shower head according to further still another embodiment.

FIG. 9 is a schematic cross sectional view of a shower head according to further still another embodiment.

### DETAILED DESCRIPTION OF THE EMBODIMENTS

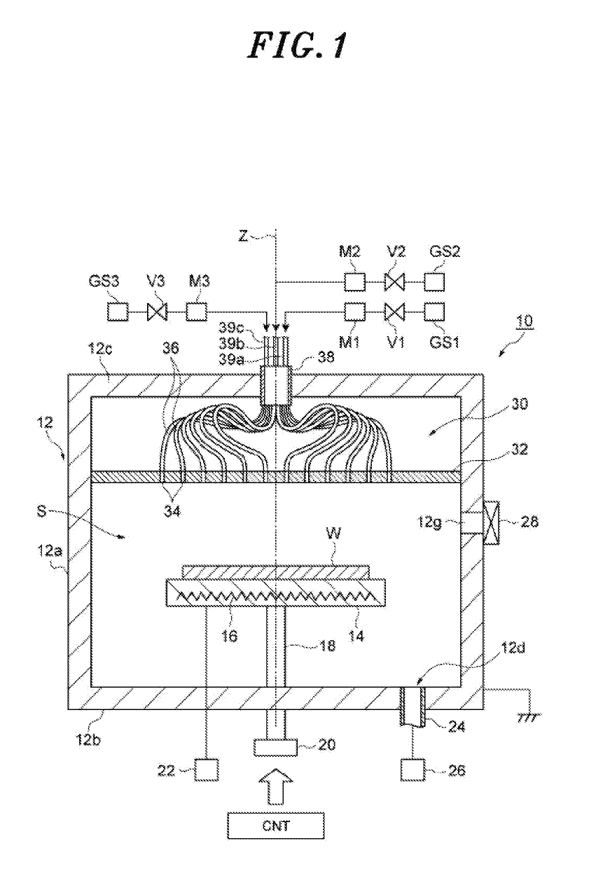

Hereinafter, various embodiments will be described in detail with reference to the accompanying drawings. Further, like reference numerals will be used for like or corresponding parts throughout the drawings, and redundant description of like or corresponding parts will be omitted. First, a film forming apparatus according td an embodiment will be described. FIG. 1 schematically shows the film forming apparatus according to the embodiment. In FIG. 1, a cross sectional structure of a film forming apparatus 10 is schematically illustrated. The film forming apparatus 10 is an apparatus for forming a thin film on a target object by using an ADD method.

The film forming apparatus 10 includes a substantially cylindrical processing chamber 12. The processing chamber 12 has a sidewall 12a, a bottom wall 12h and a top wall 12c. The processing chamber 12 defines therein a processing space S. The sidewall 12a has a cylindrical shape and extends along the Z-axis direction. The bottom wall 12b and the top wall 12c are provided at a lower end side and an upper end side of the sidewall 12a, respectively. The processing chamber 12 is made of, e.g., aluminum.

A gas exhaust line 24 having a gas exhaust port 12d is provided at the bottom wall 12b of the processing chamber 12 The gas exhaust line 24 is connected to a gas exhaust unit 26. The gas exhaust unit 26 includes a vacuum pump such as a turbo molecular pump or the like. By using the gas exhaust unit 26, a pressure in the processing space S in the processing chamber 12 can be reduced to a desired vacuum level. A loading/unloading port 12g for the target object W is provided at the sidewall 12a of the processing chamber 12. A gate valve 28 for opening/closing the loading/unloading port 12g is provided at the loading/unloading port 12g.

A mounting table is provided in the processing chamber 12. The mounting table 14 has a substantially disc shape. The mounting table 14 is disposed such that the central axis thereof coincides with the Z axis. The target object W is mounted on the mounting table 14. The mounting table 14 is axially supported by a supporting shaft 18 to be rotatable about the Z axis. The supporting shaft 18 extends in the Z-axis direction below the mounting table 14. A driving unit 20 is connected to a lower end of the supporting shaft 18. The driving unit 20 receives a control signal from a control unit Cnt to be described later and rotates the supporting shaft 18 about the Z axis at a rotational speed determined by the control signal.

A heater 16 is provided in the mounting table 14. The heater 16 is connected to a heater power supply 22. The target object W is heated by heat generated by power supplied from the heater power supply 22.

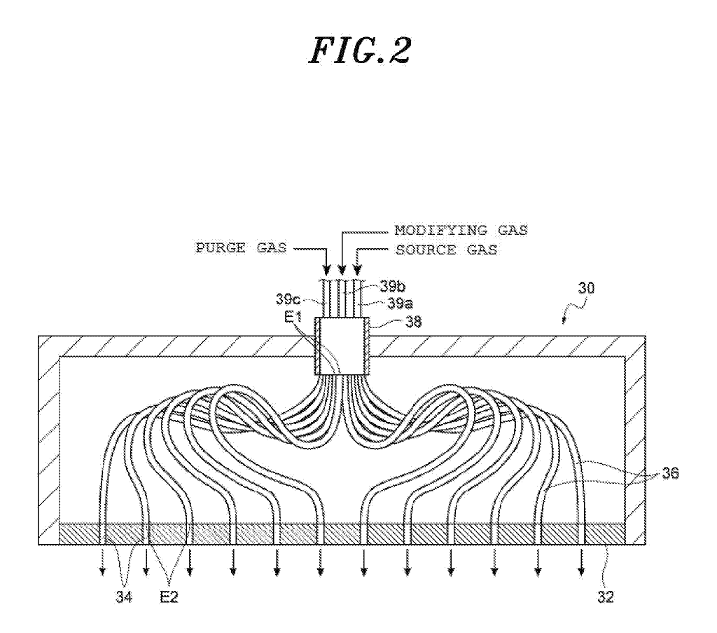

A shower head 30 is provided at an upper portion of the processing chamber 12. Hereinafter, the shower head 30 will be described with reference to FIGS. 1 to 3. FIG. 2 is a cross sectional view schematically showing a shower head according to an embodiment. The shower head according to the embodiment injects a gas supplied from a gas source in a shower shape toward the target object W. The shower head 30 includes a gas injection plate 32, a plurality of tubes 36, and a reservoir 38.

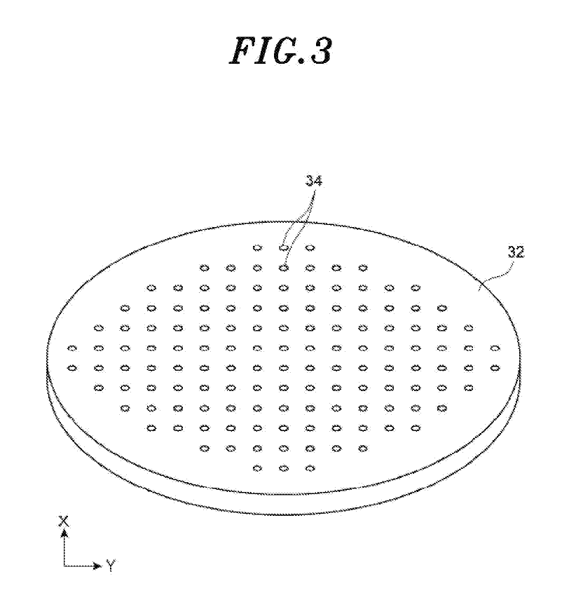

The gas injection plate 32 is disposed such that central axis coincides with the Z axis. The gas injection plate 32 faces the mounting table 14 with the processing space S therebetween. FIG. 3 is a perspective view showing, an example of the gas injection plate 32. The gas injection plate 32 has a substantially disc shape. A plurality of gas injection holes 34 extending in a thickness direction of the gas injection plate 32 is formed in the entire surface of the gas injection plate 32. The gas injection holes 34 are arranged two-dimensionally along the X direction (first direction) and the Y direction (second direction) which are orthogonal to each other in the surface of the gas injection plate 32. In other words, the gas injection holes 34 are arranged in the X direction orthogonal to the thickness direction of the gas injection 32 and in the Y direction orthogonal to the thickness direction and the direction.

The reservoir 38 is provided at the top wall 12c of the processing chamber 12. The reservoir 38 is, e.g., a tubular body having closed opposite ends and defines therein a space for gas diffusion. One ends of gas supply tubes 39a to 39c are connected to the reservoir 38 to communicate with the inner space of the reservoir 38. The other end of the gas supply tube 39a is connected to a gas source GS1 via a flow rate controller M1 and a valve V1. The other end of the gas supply tube 39b is connected to a gas source GS2 via a flow rate controller M2 and a valve V2. The other end of the gas supply tube 39c is connected to a gas source GS3 via a flow rate controller M3 and a valve V3.

The gas sources GS1 to GS3 are gas sources of a source gas for forming a thin film, a modifying gas for modifying a thin film, and a purge gas, respectively. The purge gas is used for discharging a gas remaining in the shower head 30 to the outside. The purge gas is, e.g., hydrogen gas or nitrogen gas. The valves V1 to V3 switch supply of gases from the gas sources GS1 to GS3 and stop of the gas supply. The flow rate controllers M1 to M3 are, e.g., mass controllers, and used for controlling flow rates of the gases from the gas sources GS1 to GS3, respectively. The reservoir 38 functions as a common flow path for diffusing the gases supplied from the gas sources GS1 to GS3 in the inner space thereof and distributing the diffused gases to the plurality of tubes 36.

The tubes 36 have one ends E1 and the other ends E2. The one ends E1 of the tubes 36 are connected to the reservoir 38 to communicate with the inner space of the reservoir 38. The other ends E2 of the tubes 36 are connected to the gas injection holes 34 of the gas injection plate 32. The tubes 36 are flexible and made of, e.g., Teflon (Registered Trademark). Further, the tubes 36 may be stainless steel tubes that are bent. Moreover, the tubes 36 may have substantially the same inner diameter. The tubes 36 provide a plurality of flow paths for guiding the gases that have been introduced into the reservoir 38 from the gas sources GS1 to GS3 to the gas injection holes 34. The tubes 36 serve as a gas supply unit for guiding the gases from the reservoir 38 to the gas injection holes 34.

Each of the tubes 36 is bent between the gas injection plate 32 and the reservoir 38. In other words, each of the tubes 36 has a length longer than a linear distance between one end E1 and the other end E2. Hereinafter, relation between the tubes 36 will be described by using any two tubes selected among the tubes 36.

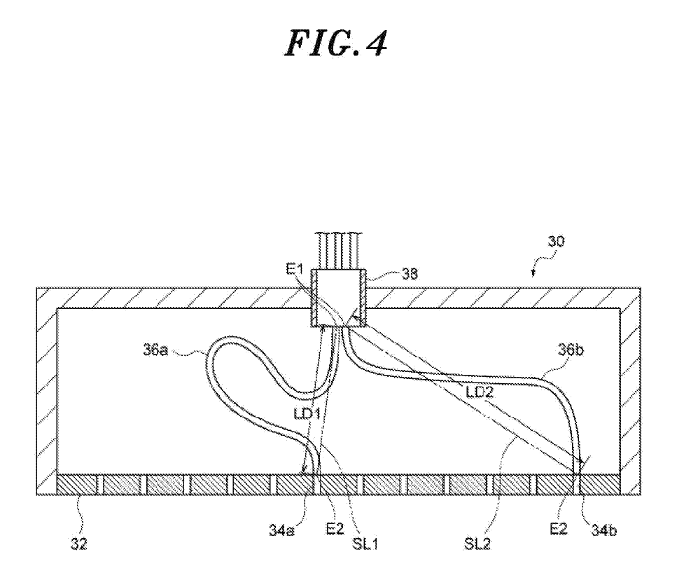

FIG. 4 is a schematic cross sectional view showing a first tube 36a and a second tube 36b which are randomly selected among the tubes 36 of the shower head 30 shown in FIG. 2. The first tube 36a has one end E1 connected to the reservoir 38 and the other end E2 connected to a gas injection hole 34a. The second tube 36b has one end E1 connected to the reservoir 38 and the other end E2 connected to a gas injection hole 34b. The gas injection hole 34a is formed at a position close to the reservoir 38 compared to the gas injection hole 34b. In other words, a first linear distance LD1 between the position of one end E1 of the first tube 36a and the position of the other end E2 of the first tube 36a is smaller than a second linear distance between the position of one end E1 of the second tube 36b and the position of the other end E2 of the second tube 36b. In other words, the first linear distance LD1 and the second linear distance LD2 are different from each other.

The first tube 36a and the second tube 36b have lengths longer than the first linear distance LD1 and the second linear distance LD2, respectively. On the assumption that a virtual linear line connecting the reservoir 38 and the gas injection hole 34a, i.e., a virtual linear line connecting the position of one end E1 and the position of the other end E2 of the first tube 36a, is a linear line SL1, the first tube 36a extends from a connecting position with the reservoir 38 in a direction away from the linear line SL1, and is bent to extend in a direction toward the linear line SL1, and then is connected to the gas injection hole 34a. In the same manner, on the assumption that a virtual linear line connecting the reservoir 38 and the gas injection hole 34b, i.e., a virtual linear line connecting the position of one end E1 and the position of the other end E2 of the first tube 36b, is a linear line SL2, the second tube 36b extends from a connecting position with the reservoir 38 in a direction away from the linear line SL2, and is bent to extend in a direction toward the linear line SL2, and then is connected to the gas injection hole 34b.

Here, a difference between the length of the first tube 36a, i.e., the length of the flow path provided by the first tube 36a, and the first linear distance LD1 is greater than a difference between the length of the second tube 36b, i.e., the length of the flow path provided by the second tube 36b and the second linear distance LD2. In other words, on the assumption that a difference between the linear distance between the reservoir 38 and the gas injection hole 34 and a length of a corresponding flow path is an extra length, an extra length of the flow path provided by the first tube 36a is greater than an extra length of the flow path provided by the second tube 36b. Based on the above relation, the difference in the length between the flow path provided by the first tube 36a and the flow path provided by the second tube 36b can be reduced and, thus, the difference in conductance between the flow paths can be reduced. As a result, the difference between the flow rates of the gases injected from the gas injection holes 34 can be reduced. In one embodiment, the tubes 36 may have the same length.

Referring back to FIG. 1, in one embodiment, the film forming apparatus 10 may further include the control unit Cnt. The control unit Cnt is a computer including a processor, a storage unit, an input device, a display device and the like, and controls the respective components of the film forming apparatus 10. Specifically, the control unit Cnt is connected to the valves V1 to V3, the flow rate controllers M1 to M3, the heater power supply 22, and the gas exhaust unit 26.

The control unit Cnt is driven by a program based on an it recipe and sends a control signal. By the control signal from the control unit Cnt, it is possible to select gases supplied from the gas sources and control flow rates of the gases supplied from the gas sources, the power supply of the heater power supply 22 and the exhaust operation of the gas exhaust unit 26.

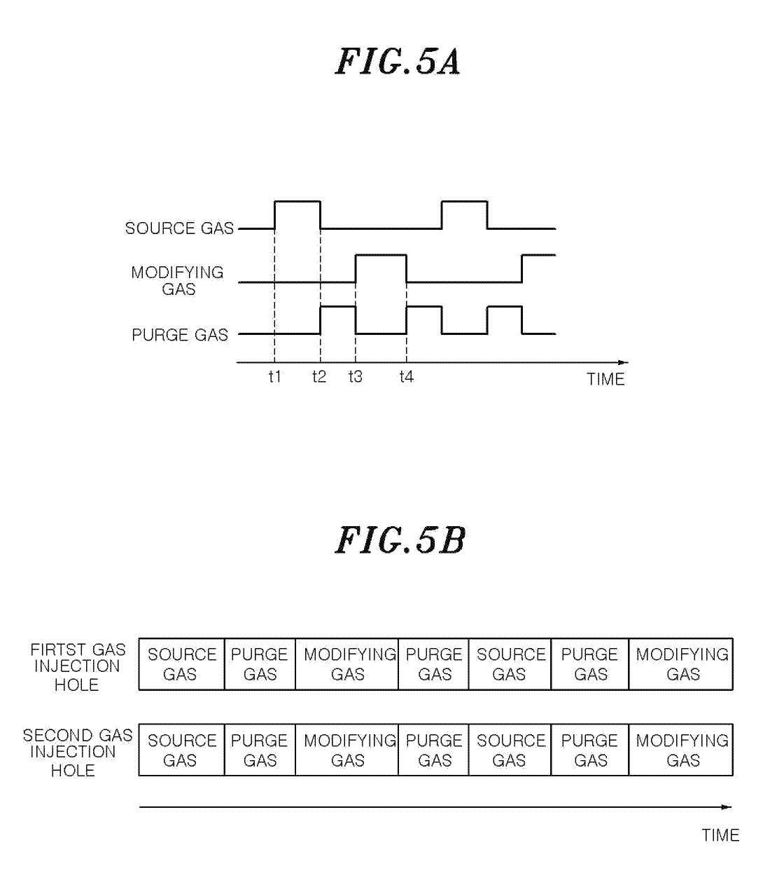

Hereinafter, an operation and an operational effect of the film forming apparatus according to the embodiment will be described. FIG. 5A is a timing chart showing flow rates of gases supplied from the gas sources GS1 to GS3 to the reservoir 38. In the case of forming a thin film on the target object W, first, at time t1, a source gas is supplied from the gas source to the reservoir 38. The source gas supplied to the reservoir 38 is injected toward the target object W through the tubes 36 and the gas injection holes 34. The source gas injected toward the target object W is decomposed by heat generated the heater 16 and a thin film derived from the source gas is formed on the target object.

Next, at time t2, the supply of the source gas is stopped, and the purge gas is supplied from the gas source GS3 to the reservoir 38. The purge gas supplied to the reservoir 38 pushes out the source gas remaining in the reservoir 38 and the tubes 36 to the processing space through the gas injection holes 34. The source gas pushed out to the processing space S is discharged to the outside of the film forming apparatus 10 through the gas exhaust port 12d. Then, at time t3, the supply of the purge gas is stopped, and the modifying gas is supplied to the reservoir 38. The modifying gas supplied to the reservoir s injected toward the target object W through the tubes 36 and the gas injection holes 34. The injected modifying gas modifies the thin film formed on the target object W. Thereafter, at time t4, the supply of the modifying gas, is stopped, and the purge gas is supplied from the gas source GS3 to the reservoir 38. The purge gas supplied to the reservoir 38 pushes out the modifying gas remaining in the reservoir 38 and the tubes 36 to the processing space S through the gas injection holes 34. The modifying gas pushed out to the processing space S is discharged to the outside of the film forming apparatus 10 through the gas exhaust port 12d. Next, by repeating the same operations as those executed from time t1 to t4, a thin film having a desired film thickness is formed on the target object.

FIG. 5B shows timings of injection of gases from the first and the second gas injection hole which are randomly selected among the gas injection holes 34. In the shower head according to the embodiment, the difference in conductance between the flow paths provided by the tubes 36 is reduced. Therefore, as can be seen from FIG. 5B, temporal difference in the gas injection from the first and the second gas injection hole is reduced. Accordingly, various gases supplied to the processing space S switched substantially at the same timing in the gas injection holes 34.

When the gases are injected at different timings, a gas injected from a gas injection hole where the injection is relatively slow may flow backward into the shower head through another gas injection hole, which may result in mixing of the source gas and the modifying gas. If the source gas and the modifying gas are mixed, particles are generated on the target object. By using the shower head 30, the temporal difference in the gas injection from the first gas injection hole and the second gas injection hole reduced. Accordingly, when the source gas and the modifying gas are switched, the gas replacement is carried out at the same time in any of the flow paths. As a result, gas supply and stop of the gas supply can be switched at the same time in all the gas injection holes, thereby preventing the source gas and the modifying gas from being mixed. In addition, by using the shower head 30, the difference in conductance between the tubes 36 is reduced and, thus, it is possible to uniformly distribute the gases supplied to the reservoir 38 to the tubes 36. Accordingly, the difference between the flow rates of the gases injected from the gas injection holes 34 can be reduced. As a result, deterioration of the in-plane uniformity of the target object W can be suppressed.

Hereinafter, a shower head according to another embodiment will be described.

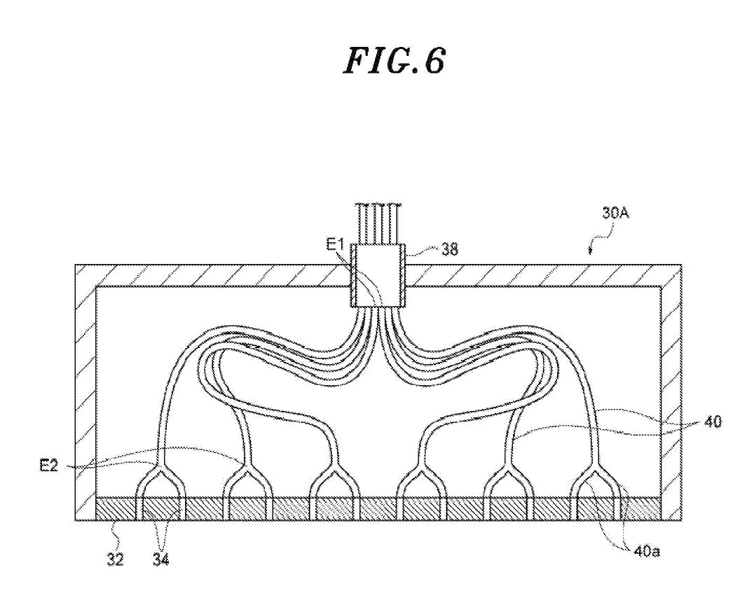

FIG. 6 is a cross sectional view schematically showing the shower head according to another embodiment. A shower head 30A shown in FIG. 6 is different from the shower head 30 in that each of a plurality of tubes is branched. The shower head 30A includes a plurality of tubes 40 instead of the tubes 36. One ends E1 of the tubes 40 are connected to the reservoir 38 and the other end E2 of the tubes 40 are connected to branch tubes 40a. Each of the branch tubes 40a has an end connected to a corresponding gas injection hole. In other words, the branch tubes 40a provide branch flow paths that respectively connect the other ends E2 of the tubes 40 to the corresponding gas injection holes 34.

In this shower head 30A as well, any two tubes selected among the tubes 40 have the same relation as that of any two tubes selected among the tubes 36. Therefore, this shower head 30A as well, the difference in conductance between the flow paths provided by the tubes 40 can be reduced. Accordingly, the same effect as that of the shower head 30 can be obtained. Further, by using the shower head 30A, the number of tubes 40 can be reduced and, thus, the shower head can be scaled down. In the example shown in FIG. 6, two branch tubes 40a have ends connected to two gas injection holes 34. However, there may be provided three or more branch tubes 40a which have ends connected to three or more gas injection holes The branch tubes 40a may be connected to the other end E2 of at least one of the tubes 40.

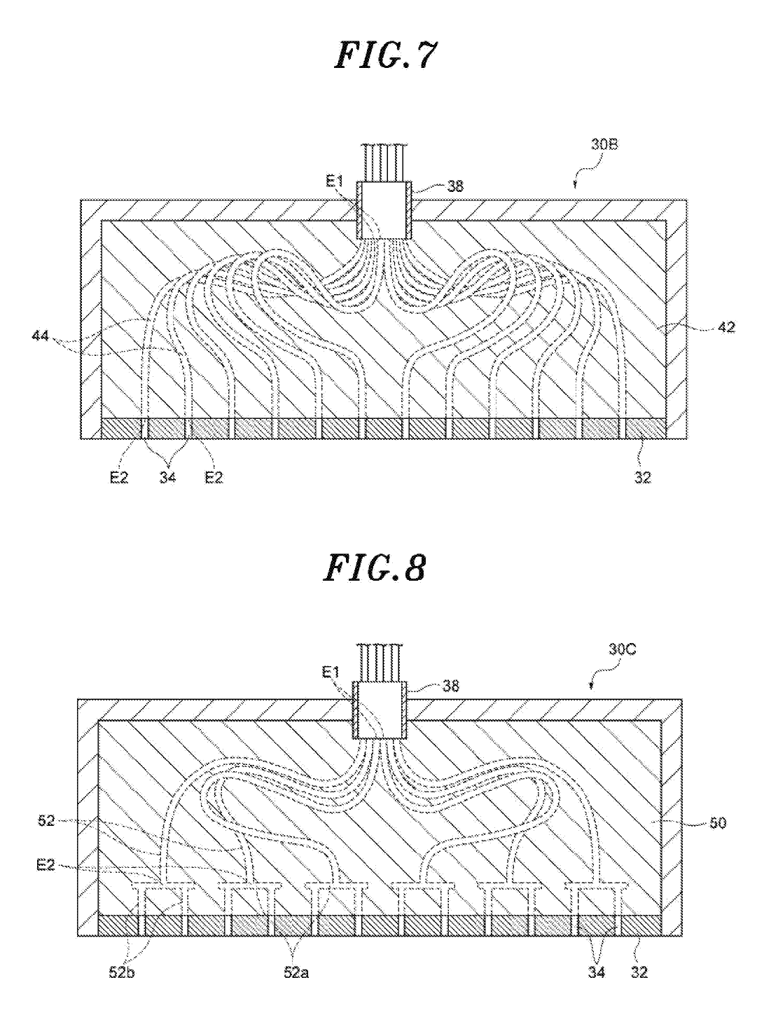

Still another embodiment will be described. FIG. 7 is a cross sectional view schematically showing a shower head according to still another embodiment. A shower head 30B shown in FIG. 7 is different from the shower head 30 in that a block body 42 is provided, instead of the tubes 36, between the gas injection plate 32 and the reservoir 38. The block body 42 has, e.g., a cylindrical shape and is a block-shaped member formed as one unit by using a material such as resin, metal or the like.

A plurality of channels having a small diameter is formed in the block body 42 to penetrate therethrough along curved routes extending from a top surface to a bottom surface thereof. The channels 44 have one ends E1 communicating with the reservoir 38 and the other ends E2 communicating with the gas injection holes 34. The channels constitute a plurality of flow paths that connects the reservoir 38 and the gas injection holes 34. Further, the channels 44 are formed in the block body 42 to pass through the same routes as those of the flow paths provided by the tubes 36. The block body 42 having the channels 44 can be manufactured by using, e.g., a 3D printer. By using the shower head 30B, the same effect as that of the shower head 30 can be obtained. In addition, since the channels 44 form a plurality of flow paths, the number of components of the shower head can be reduced. As a result, the shower head can be scaled down.

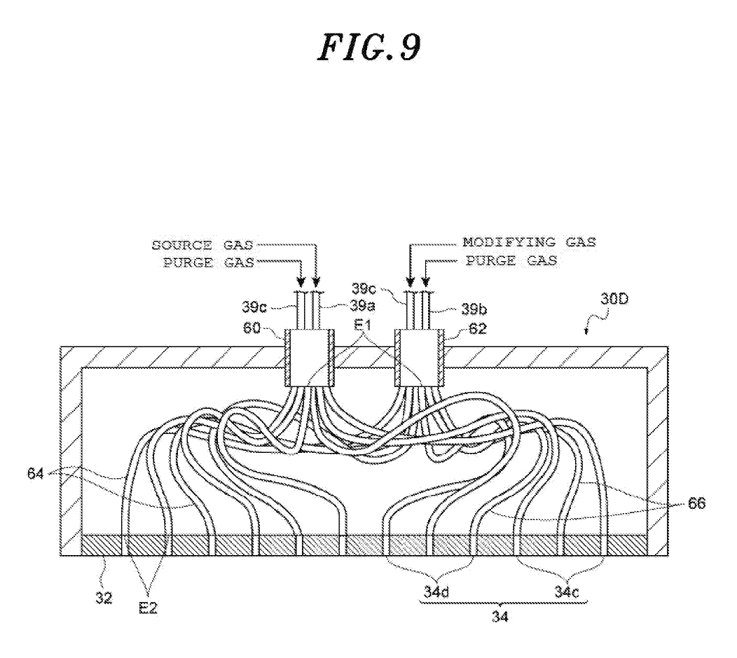

Further still another embodiment will be described. FIG. 8 is a cross sectional view schematically showing a shower head according to further still another embodiment. A shower head 30C shown in FIG. 8 has a block body 50 between. the gas injection plate 32 and the reservoir 38, as in the case of the shower head 30B. However, the shape of the channels formed in the block body 50 of the shower head 300 is different from that of the channels formed in the block body 42 of the shower head 30B. A plurality of channels 52 is formed in the block body 50 of the shower head 305. Further, a plurality of gas diffusion spaces 52a is formed in the block body 50. One ends E1 of the channels 52 are connected to the reservoir 38. The other ends E2 of the channels 52 are connected to the gas diffusion spaces 52a.

Each of the gas diffusion spaces 52a communicates with a few gas injection holes 34 through a few branch channels 52b. In this shower head 30C as well, the difference in the length between the flow paths provided by the channels 52 can be reduced and, thus, the same effect as that of the shower head 30 can be obtained. Further, since the shower head 300 has the gas diffusion spaces 52a formed in the block body 50, a volume of each of the gas diffusion spaces can be reduced. As a result, compared to when a single gas diffusion space is formed in the shower head, stationary gas flow in the gas diffusion spaces can be suppressed. In the example shown in FIG. 8, the gas diffusion space 52a communicates with two gas injection holes 34. However, the gas diffusion space 52a may communicate with three or more gas injection holes 34.

Still further another embodiment will be described. FIG. 9 is a cross sectional view schematically showing a shower head according to still further another embodiment. A shower head 30D shown in FIG. 9 is different from the shower head 30 shown in FIG. 2 in that two reservoirs are provided and connected to a plurality of gas injection holes through a plurality of flow paths. The shower head 30D includes a first reservoir (one reservoir) 60 and a second reservoir (another reservoir) 62, instead of the reservoir 38. The first reservoir 60 is connected to gas supply tubes 39a and 39c, and a source gas and a purge gas may be supplied from the gas sources GS1 and GS3 to the first reservoir 60. The second reservoir 62 is connected to gas supply tubes 39b and 39c, and a modifying gas and a purge gas may be supplied from the gas sources GS2 and GS3 to the second reservoir 62.

The shower head 30D includes a plurality of tubes 64 and a plurality of tubes 66. One ends E1 of the tubes 64 are connected to the first reservoir 60. The other ends E2 of the tubes 64 are connected to every other gas injection holes 34c in the X direction and the Y direction among a plurality of gas injection holes 34 formed in the gas injection plate 32 along the X direction and the Y direction. One ends E1 of the tubes 66 are connected to the second reservoir 62. The other ends E2 of tubes 66 are connected to every other gas injection holes 34d that are not connected to the other ends E2 of the tubes 64 among the gas injection holes 34. In other words, the other ends E2 of the tubes 64 and the other ends E2 of the tubes 66 are alternately connected to the gas injection holes 34 in the X direction and the Y direction. The tubes 64 provide a plurality of flow paths. The tubes 66 provide a plurality of other flow paths.

Any two tubes selected among the tubes 64 and any two tubes selected among the tubes 66 have the same relation as any two tubes selected among the tubes 36. In other words, among the tubes 64, any two tubes 64 that satisfy a condition that a first linear distance between the positions of one end E1 and the other end E2 of one tube 64 is shorter than a second linear distance between the positions of one end E1 and the other end E2 of the other tube 64 have relationship in which the difference between the length of the one tube 64 and the first linear distance is larger than the difference between the length of the other tube 64 and the second linear distance. Among the tubes 66, any two tubes 66 that satisfy a condition that a third linear distance between the positions of one end E1 and the other end E2 of one tube 66 is shorter than a fourth linear distance between the positions of one end E1 and the other end E2 of the other tube 66 have relationship in which the difference between the length of the one tube 66 and the third linear distance is larger than the differences between the length of the other tube 66 and the fourth linear distance. In other words, one tube connected to the gas injection hole 34c that is relatively close to the first reservoir 60 has an extra length larger than that of the other tube connected to the gas injection hole 34c that is relatively far from the first reservoir 60. Further, one tube connected to the gas injection hole 34d that is relatively close to the second reservoir 62 has an extra length larger than that of the other tube connected to the gas injection hole 34d that is relatively far from the second reservoir 62. The shower head 30D can provide the same effect as that of the shower head 30. In the shower head 30D, a source gas supply path and a modifying gas supply path are separated, so that the mixing of the source gas and the modifying gas can be reliably prevented.

While various embodiments have been described, various modifications can be made without being limited to above-described embodiments. For example, the above-described film forming apparatus 10 is configured as a thermal ALD apparatus. However, the shower heads 30, 30A, 30B, 30C and 30D of the embodiments may be employed for any film forming apparatus. For example, the shower heads 30, 30A, 30B, 30C and 30D may be employed for a plasma ALD apparatus, a thermal CVD apparatus, a plasma CVD apparatus, a plasma etching apparatus, and a plasma ALE (Atomic Layer Etching) apparatus.

The above-described various embodiments may be combined without contradicting each other. For example, the shower head 30D shown in FIG. 9 may include branch tubes that connect the other ends E2 of the tubes 64 to a few gas injection holes 34c and branch tubes that connect the other ends of the tubes 66 to a few gas injection holes 34d. Further, the shower head 30D may include a block-shaped body provided with a plurality of channels which form a plurality of flow paths.

In the embodiment illustrated in FIG. 9, the gas injection holes 34 are arranged in the X direction and the Y direction. However, the gas injection holes 34 may be arranged in the circumferential direction and the radial direction of the gas injection plate when viewed from the thickness direction of the gas injection plate. In that case, the other ends E2 of the tubes 64 and the other ends E2 of the tubes 66 may be alternately connected to the gas injection holes 34 in the circumferential direction and the radial direction of the gas injection plate.

### DESCRIPTION OF REFERENCE NUMERALS

10: film forming apparatus
12: processing chamber
14: mounting table
16: heater
30, 30A, 30B, 30C, 30D: shower head
32: gas injection plate
34: gas injection hole, 36, 40, 64
66: tube
38: reservoir
42, 50: block body
44, 52: channel
60: first reservoir
62: second reservoir
LD1: first linear distance
LD2: second linear distance
S: processing space
W: target object
Z: axis

1. A shower head for a film forming apparatus, comprising:
a gas injection plate provided with a plurality of gas injection holes extending in a thickness direction thereof; and
a gas supply unit configured to provide a plurality of flow paths that guide gas to at least a part of the plurality of gas injection holes from a common flow path, each of the plurality of flow paths having one end connected to the common flow path and the other end,
wherein among the plurality of flow paths, any two flow paths that satisfy a condition that a first linear distance between positions of one end and the other end of one flow path is shorter than a second linear distance between positions of one end and the other end of the other flow path have a relationship in which a difference between a length of the one flow path and the first linear distance is larger than a difference between a length of the other flow path and the second linear distance.

2. The shower head of claim 1, wherein the gas supply unit further provides branch flow paths that connect the other end of at least one of the plurality of flow paths to at least a few gas injection holes among the plurality of gas injection holes.

3. The shower head of claim 2, wherein the gas supply unit has a plurality of tubes that provide the plurality of flow paths and the plurality of tubes are flexible.

4. The shower head of claim 2, wherein the gas supply unit has a block-shaped member provided with a plurality of channels and the plurality of channels form the plurality of flow paths.

5. The shower head of claim 4, wherein the block-shaped member is formed by using a 3D printer.

6. The shower head of claim 1, wherein the gas supply unit further provides a plurality of other flow paths that guide gas to at least a part of the plurality of gas injection holes from another common flow path, each of the plurality of other flow paths including one end connected to the another common flow path and the other end, and
wherein among the plurality of other flow paths, any two paths that satisfy a condition that a third linear distance between positions of one end and the other end of one flow path is shorter than a fourth linear distance between positions of one end and the other end of the other flow path have a relationship in which a difference between a length of the one flow path and the third linear distance is larger than a difference between a length of the other flow path and the fourth linear distance.

7. The shower head of claim 6, wherein the plurality of gas injection holes are arranged in a first direction orthogonal to a thickness direction of the gas injection plate and in a second direction orthogonal to the thickness direction and the first direction, and
the other ends of the plurality of flow paths and the other ends of the plurality of other flow paths are alternately connected to the plurality of gas injection holes in the first direction and the second direction.

8. The shower head of claim 6, wherein the gas injection plate has a disc shape,
the plurality of gas injection holes are arranged along a circumferential direction and a radial direction of the gas injection plate when viewed from the thickness direction, and
the other ends of the plurality of flow paths and the other ends of the plurality of other flow paths are alternately connected to the plurality of gas injection holes in the circumferential direction and the radial direction.

9. A film forming apparatus comprising the shower head described in claim 1.
